(19) United States
(12) Patent Application Publication
(10) Pub. No.: US 2024/0381623 A1
(43) Pub. Date: Nov. 14, 2024

(54) SEMICONDUCTOR DEVICE AND METHOD FOR FABRICATING THE SAME

(71) Applicant: Samsung Electronics Co., Ltd., Suwon-si (KR)

(72) Inventors: Jungha LEE, Suwon-si (KR); Jiho PARK, Suwon-si (KR); Seok-Won KIM, Suwon-si (KR); Sanghyeok YU, Suwon-si (KR)

(73) Assignee: Samsung Electronics Co., Ltd., Suwon-si (KR)

(21) Appl. No.: 18/412,858

(22) Filed: Jan. 15, 2024

(30) Foreign Application Priority Data
May 10, 2023 (KR) 10-2023-0060749

(51) Int. Cl. H10B 12/00

(52) U.S. Cl. CPC H10B 12/482; H10B 12/053; H10B 12/315; H10B 12/488

(57) ABSTRACT

A semiconductor device includes a substrate; a bit line disposed on the substrate and extending in a first direction; a first interlayer insulating layer disposed on the bit line, and including a channel trench extending in a second direction crossing the first direction; a second interlayer insulating layer disposed on the first interlayer insulating layer; a channel pattern disposed in the channel trench; a word line extending in the second direction and spaced apart from the channel pattern; a gate insulating pattern disposed between the channel pattern and the word line; an insulating pattern disposed on the word line; and a landing pad connected to the channel pattern. The landing pad includes a first protrusion disposed between the channel pattern and the second interlayer insulating layer, and a second protrusion disposed between the channel pattern and the insulating pattern.

### CROSS-REFERENCE TO RELATED APPLICATION

This application claims priority to Korean Patent Application No. 10-2023-0060749 filed in the Korean Intellectual Property Office on May 10, 2023, the entire contents of which are incorporated herein by reference.

### BACKGROUND

### 1. Field

The present disclosure relates to semiconductor devices and methods for fabricating the same.

### 2. Description of the Related Art

There has been a need for semiconductor memory devices with increased integration to meet the excellent performance and lower price demanded by consumers. Increased integration of semiconductor memory devices is especially required because integration is an important factor in determining product price.

Integration of a two-dimensional or planar semiconductor memory device may be mainly determined by an area of a unit memory cell, thus being greatly affected by a level of fine pattern formation technology. However, ultra-expensive equipment may be required to implement fine patterns, and two-dimensional semiconductor memory devices may thus have increased integration that is still limited. Accordingly, proposed is a semiconductor memory device including a vertical channel transistor having a channel extending in a vertical direction.

### SUMMARY

Embodiments of the present disclosure provide a semiconductor device capable of higher reliability, and a method for fabricating the same.

Embodiments of the inventive concepts provide a semiconductor device including a substrate; a bit line on the substrate and extending in a first direction; a first interlayer insulating layer on the bit line, and including a channel trench extending in a second direction crossing the first direction; a second interlayer insulating layer on the first interlayer insulating layer; a channel pattern in the channel trench; a word line extending in the second direction and spaced apart from the channel pattern; a gate insulating pattern between the channel pattern and the word line; an insulating pattern on the word line; and a landing pad connected to the channel pattern. The landing pad includes a first protrusion between the channel pattern and the second interlayer insulating layer, and a second protrusion between the channel pattern and the insulating pattern.

Embodiments of the inventive concepts further provide a semiconductor device including a substrate; a bit line on the substrate; a channel pattern on the bit line, and extending to an upper surface of the bit line in a vertical direction; a word line crossing the bit line and spaced apart from the channel pattern; a gate insulating pattern between the channel pattern and the word line; an insulating pattern on the word line; and a landing pad connected to the channel pattern. The landing pad surrounds an upper surface and a side surface of one end of the channel pattern.

Embodiments of the inventive concepts still further provide a method for fabricating a semiconductor device including forming a bit line on a substrate; stacking a first interlayer insulating layer and a second interlayer insulating layer on the bit line; forming a channel trench by patterning the first interlayer insulating layer and the second interlayer insulating layer; forming a channel pattern in the channel trench; forming a gate insulating pattern on the channel pattern; forming a word line disposed on the gate insulating pattern, the word line crossing the bit line and spaced apart from the channel pattern; forming an insulating pattern on the word line; exposing a first surface of the channel pattern and a second surface opposite to the first surface by patterning the second interlayer insulating layer and the gate insulating pattern; and forming a landing pad covering an upper surface of the channel pattern, and covering the first surface and the second surface of the channel pattern.

As set forth above, the landing pad may surround the one end of the channel pattern by including the first protrusion and the second protrusion. Accordingly, the contact area between the channel pattern and the landing pad may be increased to lower the contact resistance therebetween, thus improving the reliability of the semiconductor memory device.

### BRIEF DESCRIPTION OF THE DRAWINGS

FIG. 1 is a layout diagram for explaining a semiconductor device according to embodiments of the inventive concepts.

FIG. 2 is a view of a cross-section of the semiconductor device that is taken along lines A-A′ and B-B′ of FIG. 1.

FIG. 3 a view of a cross-section of the semiconductor device that is taken along line C-C′ of FIG. 1.

FIG. 4 is an enlarged cross-sectional view showing a region P1 of FIG. 2.

FIGS. 5 and 6 are perspective views each showing landing pads of the semiconductor device according to example embodiments.

FIGS. 7, 8, 9 and 10 are enlarged cross-sectional views each corresponding to the region P1 of FIG. 2, showing a semiconductor device according to example embodiments.

FIGS. 11, 12, 13, 14, 15, 16 and 17 are cross-sectional views each showing a method for fabricating a semiconductor device according to example embodiments.

FIG. 18 is an enlarged cross-sectional view showing a region P2 of FIG. 17.

FIGS. 19 and 20 are enlarged cross-sectional views corresponding to the region P2 of FIG. 17, each showing a method for fabricating a semiconductor device according to example embodiments.

FIGS. 21 and 22 are cross-sectional views each showing a method for fabricating a semiconductor device according to example embodiments.

### DETAILED DESCRIPTION

Hereinafter, embodiments of the present disclosure are described in detail with reference to the accompanying drawings for those skilled in the art to which the present disclosure pertains to easily practice the present disclosure. The present disclosure may be modified in various different forms, and is not limited to the embodiments provided in the specification. The same or similar components are denoted by the same reference numeral throughout the specification.

The size and thickness of each component shown in the accompanying drawings are arbitrarily shown for convenience of explanation, and therefore, the present disclosure is not necessarily limited to contents shown in the drawings. The thicknesses are exaggerated in the drawings in order to clearly represent several layers and region. In addition, the thicknesses of some layers and regions are exaggerated in the drawings for convenience of explanation.

When an element such as a layer, a film, a region or a substrate is referred to as being “on” or “above” another element, the element may be “directly on” another element, or may have a third element interposed therebetween. On the other hand, when an element is referred to as being “directly on” another element, there is no third element interposed therebetween. When an element is referred to as being “on” or “above” a reference element, the element may be positioned on or below the reference element, and may not necessarily be “on” or “above” the reference element in an opposite direction of gravity.

Further, throughout the specification, an expression “on the plane” may indicate a case where a target is viewed from the top, and an expression “on the cross section” may indicate a case where a cross section of the target taken along a vertical direction is viewed from its side.

When the terms “about” or “substantially” are used in this specification in connection with a numerical value, it is intended that the associated numerical value includes a manufacturing or operational tolerance (e.g., ±10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes. When ranges are specified, the range includes all values therebetween such as increments of 0.1%.

Also, for example, “at least one of A, B, and C” and similar language (e.g., “at least one selected from the group consisting of A, B, and C”) may be construed as A only, B only, C only, or any combination of two or more of A, B, and C, such as, for instance, ABC, AB, BC, and AC.

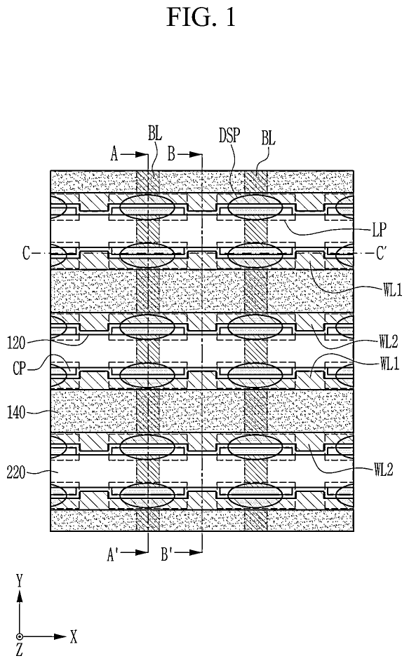

Hereinafter, a semiconductor device according to embodiments of the inventive concepts is described with reference to FIGS. 1 to 4.

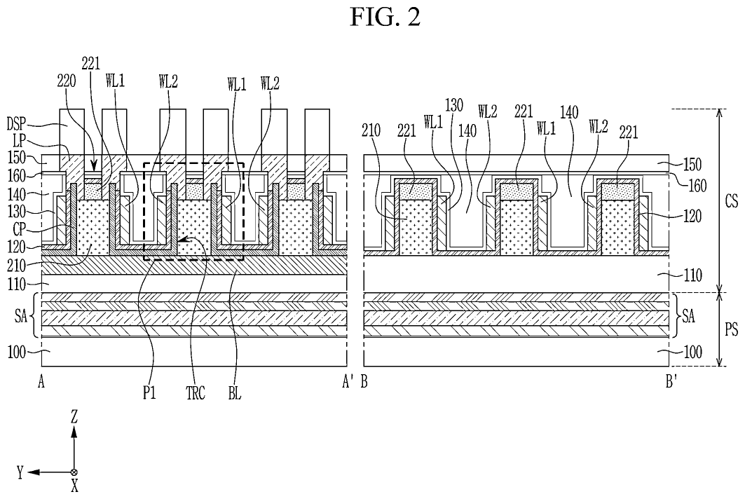

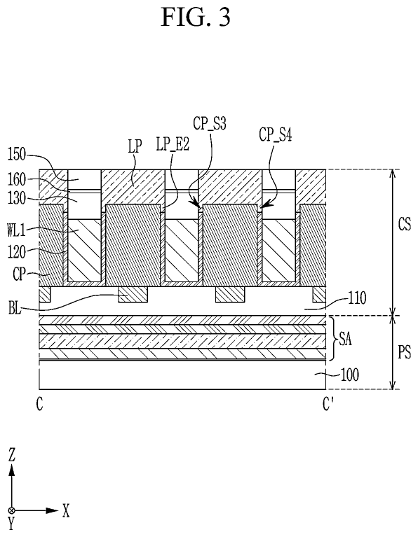

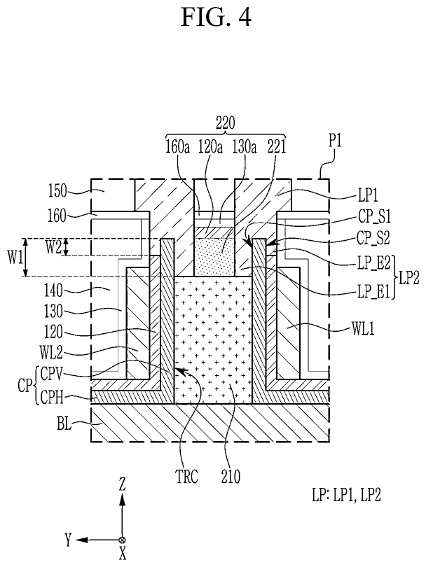

FIG. 1 is a layout diagram for explaining a semiconductor device according to example embodiments; FIG. 2 is a view of a cross-section of the semiconductor device that is taken along lines A-A′ and B-B′ of FIG. 1; FIG. 3 is a view of a cross-section of the semiconductor device that is taken along line C-C′ of FIG. 1; and FIG. 4 is an enlarged cross-sectional view showing a region P1 of FIG. 2.

Referring to FIGS. 1 to 4, a semiconductor device according to example embodiments may include a peripheral circuit structure PS and a cell array structure CS disposed on the peripheral circuit structure PS. In example embodiments, the peripheral circuit structure PS and the cell array structure CS may be vertical to each other. For example, the cell array structure CS may be disposed on an upper surface of the peripheral circuit structure PS. However, the present disclosure is not limited thereto, and in example embodiments, the peripheral circuit structure PS and the cell array structure CS may be horizontal to each other. For example, the cell array structure CS may be disposed on a side surface of the peripheral circuit structure PS.

The peripheral circuit structure PS may include a substrate 100, and a core and peripheral circuits SA integrated on an upper surface of the substrate 100. The substrate 100 may be formed by stacking an epitaxial layer on a base substrate, and is not limited thereto. For example, in example embodiments, the substrate 100 may be a silicon substrate, a gallium arsenide substrate, a silicon germanium substrate, or a semiconductor on insulator (SOI) substrate. Hereinafter, the description describes that the substrate 100 is a silicon substrate.

The core and the peripheral circuits SA may include n-channel metal-oxide semiconductor (nMOS) and p-channel metal-oxide semiconductor (pMOS) transistors integrated on the substrate 100. The core and the peripheral circuits SA may be electrically connected to bit lines BL through peripheral circuit wires and peripheral circuit contact plugs. That is, sense amplifiers may be electrically connected to the bit lines BL, and each sense amplifier may amplify and output a difference in voltage level detected by the pair of bit lines BL.

The cell array structure CS may include memory cells including vertical channel transistors VCT. The vertical channel transistor may have a channel extending in a direction vertical to the upper surface of the substrate 100.

The cell array structure CS of the semiconductor device according to example embodiments may include a lower insulating layer 110 and a bit line BL disposed on the peripheral circuit structure PS, a first interlayer insulating layer 210 and a second interlayer insulating layer 220 disposed on and above the bit line BL, a channel pattern CP disposed on the bit line BL, word lines WL1 and WL2 disposed on the channel pattern CP, a gate insulating pattern 120 disposed between the channel pattern CP and the word lines WL1 and WL2, and a landing pad LP electrically connected to the channel pattern CP.

The lower insulating layer 110 may cover the core, the peripheral circuits SA, peripheral circuit wires, and peripheral circuit contact plugs. The lower insulating layer 110 may include multi-layered insulating films. For example, the lower insulating layer 110 may include a silicon oxide film, a silicon nitride film, a silicon nitride oxide film, or a low-k film.

The bit line BL may be disposed on the substrate 100. For example, the lower insulating layer 110 may be disposed on the substrate 100, and the bit line BL may be disposed on the lower insulating layer 110. The lower insulating layer 110 may fill a space between the bit lines BL. In example embodiments, as shown in FIG. 3, an upper surface of a portion of the lower insulating layer 110 that is disposed between the bit lines BL may be disposed at the same level as that of an upper surface of the bit line BL.

The bit line BL may extend in a second direction (or Y direction). Each of the plurality of bit lines BL may extend in the second direction (or Y direction), and may be spaced apart from each other in a first direction (or X direction) crossing the second direction (or Y direction).

The bit line BL may include doped polysilicon, metal, conductive metal nitride, conductive metal silicide, conductive metal oxide, or a combination thereof. For example, the bit line BL may include aluminum (Al), copper (Cu), titanium (Ti), tantalum (Ta), ruthenium (Ru), tungsten (W), molybdenum (Mo), platinum (Pt), nickel (Ni), cobalt (Co), titanium nitride (TiN), tantalum nitride (TaN), tungsten nitride (WN), niobium nitride (NbN), titanium aluminum (TiAl), titanium aluminum nitride (TiAlN), titanium silicide (TiSi), titanium silicide nitride (TiSiN), tantalum silicate (TaSi), tantalum silicon nitride (TaSiN), ruthenium titanium nitride (RuTiN), nickel-silicide (NiSi), cobalt monosilicide (CoSi), iridium oxide (IrOx), ruthenium oxide (RuOx), or a combination thereof, and is not limited thereto. The bit line BL may include the single or multi-layer of the material described above.

In example embodiments, the bit line BL may include a two-dimensional semiconductor material, and the two-dimensional semiconductor material may include, for example, graphene, carbon nanotube, or a combination thereof.

The first interlayer insulating layer 210 may be disposed on the lower insulating layer 110. In example embodiments, the first interlayer insulating layer 210 may be disposed on an upper surface of the bit line BL. The first interlayer insulating layers 210 may each extend in the first direction (or X direction) across the bit line BL and may be spaced apart from each other in the second direction (or Y direction).

The first interlayer insulating layer 210 may include channel trenches TRC extending in the first direction (or X direction) across the bit lines BL and spaced apart from each other in the second direction (or Y direction). That is, as the channel trench TRC is formed in the first interlayer insulating layer 210, the first interlayer insulating layers 210 may be spaced apart from each other in the second direction (or Y direction).

An upper surface of the first interlayer insulating layer 210 may be disposed at a lower level than that of an upper surface of the channel pattern CP or that of an upper surface of the gate insulating pattern 120 described below. That is, the upper surface of the first interlayer insulating layer 210 may be closer to the upper surface of the substrate 100 than the upper surface of the channel pattern CP or the upper surface of the gate insulating pattern 120 described below.

The first interlayer insulating layer 210 may include, for example, at least one of silicon oxide, silicon nitride, and a low-k material having a lower dielectric constant than silicon oxide, and is not limited thereto.

For example, the low-k material may include at least one of flowable oxide (FOX), torene silazene (TOSZ), undoped silicate glass (USG), borosilicate glass (BSG), phosphosilicate glass (PSG), borophosphosilicate glass (BPSG), plasma enhanced tetra ethyl ortho silicate (PETEOS), fluoride silicate glass (FSG), carbon doped silicon oxide (CDO), xerogel, airgel, amorphous fluorinated carbon, organo silicate glass (OSG), parylene, bis-benzocyclobutenes (BCB), SILK, polyimide, porous polymeric material, or and combinations thereof, and is not limited thereto.

The second interlayer insulating layer 220 may be disposed on the first interlayer insulating layer 210. The second interlayer insulating layers 220 may each extend across the bit line BL in the first direction (or X direction) and may be spaced apart from each other in the second direction (or Y direction).

The second interlayer insulating layer 220 may include a material different from that of the first interlayer insulating layer 210. The second interlayer insulating layer 220 may include a material having an etch selectivity with respect to the first interlayer insulating layer 210. For example, the second interlayer insulating layer 220 may include silicon nitride, silicon nitride oxide, aluminum oxide, or a combination thereof.

A width of the second interlayer insulating layer 220 in the second direction (or Y direction) may be smaller than a width of the first interlayer insulating layer 210 in the second direction. Accordingly, the channel patterns CP may not be in contact with the second interlayer insulating layer 220.

The second interlayer insulating layer 220 may include a first layer 221, a second layer 120a, a third layer 130a, and a fourth layer 160a, sequentially stacked from the first interlayer insulating layer 210.

The first layer 221 may be disposed on the first interlayer insulating layer 210. The first layer 221 may include a material different from that of the first interlayer insulating layer 210. The first layer 221 may include a material having etch selectivity with respect to the first interlayer insulating layer 210. For example, first layer 221 may include silicon nitride.

The second layer 120a, the third layer 130a, and the fourth layer 160a may respectively be formed by the same manufacturing process as the gate insulating pattern 120, a first insulating pattern 130, and a third insulating pattern 160. Accordingly, the second layer 120a, the third layer 130a, and the fourth layer 160a may respectively have substantially the same material composition as the gate insulating pattern 120, the first insulating pattern 130, and the third insulating pattern 160. FIGS. 2 and 4 each show that the second interlayer insulating layer 220 is the multi-layer, but it is not limited thereto, and the second interlayer insulating layer 220 may be a single layer.

The channel pattern CP may be disposed on the bit line BL. The channel patterns CP may be spaced apart from each other in the second direction (or Y direction) on each bit line BL. That is, the channel patterns CP may be arranged in a matrix form by being spaced apart from each other in the first direction (or X direction) and the second direction (or Y direction) crossing each other.

The channel pattern CP may include a first source/drain region and a second source/drain region. For example, a lower part of the channel pattern CP may be connected to the bit line BL and function as the first source/drain region, an upper part of the channel pattern CP may be connected to the landing pad LP and function as a second source/drain region, and a portion of the channel pattern CP between the first source/drain region and the second source/drain region may function as a channel region. Here, a contact resistance between the channel pattern CP and the landing pad LP may be determined based on a contact area between the channel pattern CP and the landing pad LP. For example, the larger the contact area between the channel pattern CP and the landing pad LP, the lower contact resistance between the channel pattern CP and the landing pad LP.

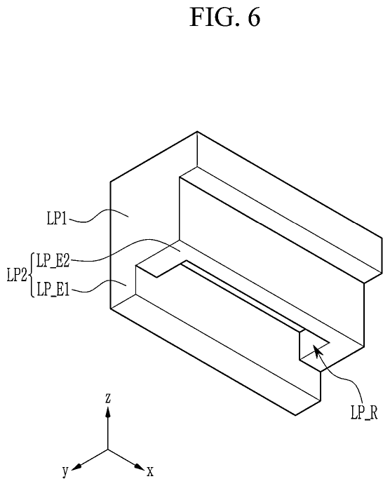

In example embodiments, the channel pattern CP may be surrounded by the landing pad LP. For example, four side surfaces of one end of the channel pattern CP may each overlap the landing pad LP in the second direction (or Y direction). The upper surface of the channel pattern CP may overlap the landing pad LP in the third direction (Z direction). That is, the channel pattern CP may penetrate into a lower surface of the landing pad LP. The channel pattern CP may fill the inside of a recess ‘LP_R’ of the landing pad (see FIG. 6) that is concave from the lower surface of the landing pad LP.

In detail and for example, one end of the channel pattern CP may include a first surface CP_S1 in contact with a first protrusion LP_E1 of the landing pad LP, a second surface CP_S2 opposite to the first surface CP_S1, a third surface CP_S3 connected to the first surface CP_S1 and the second surface CP_S2 and a fourth surface CP_S4 opposite to the third surface CP_S3. The first to fourth surfaces CP_S1 to CP_S4 of the channel pattern CP may each overlap the landing pad LP. The first to fourth surfaces CP_S1 to CP_S4 of the channel pattern CP may each be in contact with the landing pad LP. The first to fourth surfaces CP_S1 to CP_S4 of the channel pattern CP may be side surfaces of the channel pattern CP that are surrounded by the landing pad LP. A detailed description thereof is provided below.

The channel patterns CP may be disposed within the respective channel trenches TRC while being spaced apart from each other in the second direction (or Y direction). That is, the first interlayer insulating layer 210 may be disposed between the channel patterns CP adjacent to each other in the second direction (or Y direction). The channel pattern CP may be disposed between the first interlayer insulating layers 210 spaced apart from each other in the second direction (or Y direction). That is, the adjacent channel patterns CP may be separated from each other by the first interlayer insulating layer 210.

Each channel pattern CP may include a horizontal part CPH disposed on the bit line BL and extending in the second direction (or Y direction), and vertical parts CPV each extending from an end of the horizontal part CPH in the third direction (or Z direction) and opposite to each other in the second direction (or Y direction). At least a partial region of the channel pattern CP may be conformal on a profile of the channel trench TRC. For example, the horizontal portion CPH of the channel pattern CP may be disposed on the upper surface of the bit line BL while having a constant thickness (i.e., thickness in the third direction (or Z direction)). At least a partial region of the vertical portion CPV of the channel pattern CP may be disposed on a side surface of the first interlayer insulating layer 210 while having a constant width (i.e., width in the second direction (or Y direction)). Another partial region of the vertical part CPV of the channel pattern CP may be spaced apart from the second interlayer insulating layer 210 at a desired (and/or alternatively predetermined) interval. Accordingly, the channel pattern CP may have a substantially “U” shape based on the cross-section.

The channel pattern CP may protrude more than the upper surface of the first interlayer insulating layer 210 in the third direction (or Z direction). That is, the upper surface of the channel pattern CP may be disposed at a higher level than that of the upper surface of the first interlayer insulating layer 210. The upper surface of the channel pattern CP may be farther from the upper surface of the substrate 100 than the upper surface of the first interlayer insulating layer 210. The upper surface of the channel pattern CP may be disposed at substantially the same level as that of an upper surface of the first layer 221 of the second interlayer insulating layer 220. That is, the upper surface of the channel pattern CP may be disposed at substantially the same level as that of a lower surface of the second layer 120a of the second interlayer insulating layer 220. That is, the upper surface of the channel pattern CP may be disposed at substantially the same level as that of the lower surface of the second layer 120a of the second interlayer insulating layer 220 and that of the upper surface of the substrate 100. However, the present disclosure is not limited thereto, and the upper surface of the channel pattern CP may be disposed at a lower level than the upper surface of the first layer 221 of the second interlayer insulating layer 220.

The channel pattern CP may include an oxide semiconductor material. The oxide semiconductor material may include, for example, indium gallium zinc oxide (IGZO), indium gallium silicon oxide (IGSO), Indium tin zinc oxide (ITZO), indium gallium tin oxide (IGTO), indium zinc oxide (IZO), zinc oxide (ZnO), zinc tin oxide (ZTO), zinc oxynitride (ZnON), zirconium zinc tin oxide (ZZTO), tin oxide (SnO), hafnium indium zinc oxide (HIZO), gallium zinc tin oxide (GZTO), aluminum zinc tin oxide (AZTO), ytterbium gallium zinc oxide (YGZO), indium gallium oxide (IGO), or a combination thereof. For example, the channel pattern CP may include the single or multi-layer of the oxide semiconductor material described above.

As another example, the channel pattern CP may include silicon, germanium, silicon-germanium, or a combination thereof. As still another example, the channel pattern CP may include a two-dimensional semiconductor material. The two-dimensional semiconductor material may include, for example, graphene, carbon nanotube, or the combination thereof.

The word lines WL1 and WL2 may be disposed on the channel patterns CP. The word lines WL1 and WL2 may be disposed across the bit lines BL and extend in the first direction (or X direction) and spaced apart from each other in the second direction (or Y direction). Each of the word lines WL1 and WL2 may be spaced apart from the bit lines BL in the third direction (or Z direction) and may cross the bit line BL. The pair of word lines WL1 and WL2 may be disposed between the pair of vertical parts CPV of the channel pattern CP in the channel trench TRC, the pair of vertical parts CPV being opposite to each other.

In detail and for example, each of the word lines WL1 and WL2 may include one surface and the other surface opposite to one surface, and one surface of the word line WL1 and one surface of the word line WL2 may be disposed between the channel patterns CP while being opposite to each other.

One surface of the word line WL1 or WL2 may be in contact with the first insulating pattern 130 described below, and the other surface of the word line WL1 or WL2 may be in contact with the gate insulating pattern 120 described below.

The word line WL1 or WL2 may include an upper surface and a lower surface that are opposite to each other in the third direction (or Z direction). The upper surface of the word line WL1 or WL2 may be in contact with the first insulating pattern 130 described below, and face the landing pad LP while having the first insulating pattern 130 interposed therebetween.

A lower surface of the word line WL1 or WL2 may be in contact with the gate insulating pattern 120 described below, and face the bit line BL while having the gate insulating pattern 120 and the channel pattern CP interposed therebetween.

The word line WL1 or WL2 may include doped polysilicon, metal, conductive metal nitride, conductive metal silicide, conductive metal oxide, or a combination thereof. For example, the word line WL1 or WL2 may include aluminum (AI), copper (Cu), titanium (Ti), tantalum (Ta), ruthenium (Ru), tungsten (W), molybdenum (Mo), platinum (Pt), nickel (Ni), cobalt (Co), titanium nitride (TiN), tantalum nitride (TaN), tungsten nitride (WN), niobium nitride (NbN), titanium aluminum (TiAl), titanium aluminum nitride (TiAlN), titanium silicide (TiSi), titanium silicide nitride (TiSiN), tantalum silicate (TaSi), tantalum silicon nitride (TaSiN), ruthenium titanium nitride (RuTiN), nickel-silicide (NiSi), cobalt monosilicide (CoSi), iridium oxide (IrOx), ruthenium oxide (RuOx), or a combination thereof, and is not limited thereto.

The word line WL1 or WL2 may include the single or multi-layer of the above material. In example embodiments, the word line WL1 or WL2 may include the two-dimensional semiconductor material, and the two-dimensional semiconductor material may include, for example, graphene, carbon nanotube, or a combination thereof.

The gate insulating pattern 120 may be disposed between the channel pattern CP and the word line WL1 or WL2. The gate insulating pattern 120 may be conformal on a profile of the channel pattern CP. The gate insulating pattern 120 may be disposed on an upper surface of the horizontal part CPH of the channel pattern CP and disposed on a side surface of the vertical part CPV. The gate insulating pattern 120 may have a substantially “U” shape in the cross-section.

In detail and for example, the gate insulating pattern 120 may be disposed between the lower surface of the word line WL1 or WL2 and the horizontal part of the channel pattern CP, between the first insulating pattern 130 and the horizontal part of the channel pattern CP, and between the side surface of the word line WL1 or WL2 adjacent to the channel pattern CP and a portion of the vertical part CPV of the channel pattern CP.

One surface of the gate insulating pattern 120 may be in contact with the channel pattern CP, and the other surface of the gate insulating pattern 120 may be in contact with the word lines WL1 and WL2. The upper surface of the gate insulating pattern 120 may be in contact with the landing pad LP.

The upper surface of the gate insulating pattern 120 may be disposed at a lower level than that of the upper surface of the channel pattern CP.

That is, the upper surface of the gate insulating pattern 120 may be closer to the upper surface of the substrate 100 than the upper surface of the channel pattern CP

Accordingly, a side surface of a portion of the landing pad LP disposed on the gate insulating pattern 120 may be in contact with one side surface of the channel pattern CP.

A portion of the gate insulating pattern 120 may protrude more than the upper surfaces of the word lines WL1 and WL2 in the third direction (or Z direction). That is, the upper surface of the gate insulating pattern 120 may be disposed at a higher level than that of the upper surfaces of the word lines WL1 and WL2. Accordingly, a lower surface of a portion of the landing pad LP that is disposed on the gate insulating pattern 120 may not be in contact with the upper surface of the word line WL1 or WL2. Accordingly, the gate insulating pattern 120 may prevent a short circuit occurring between the word lines WL1 and WL2 and the landing pad LP.

The gate insulating pattern 120 may include aluminum oxide (Al₂O₃), silicon oxide (SiO₂), or a combination thereof. The gate insulating pattern 120 may include the low-k material having a lower dielectric constant than silicon oxide (SiO₂). For example, the gate insulating pattern 120 may include silicon nitride (SiON), silicon carbonate nitride (SiCON), or a combination thereof. However, the material included in the gate insulating pattern 120 is not limited thereto, and may be variously changed.

A width of the gate insulating pattern 120 in the second direction (or Y direction) may be smaller than or equal to a width of the vertical part CPV of the channel pattern CP in the second direction (or Y direction). For example, a ratio of the gate insulating pattern 120 to the vertical part CPV of channel pattern CP in the second direction (or Y direction) may be 5:10 to 6:10. As another example, a ratio of the gate insulating pattern 120 to the vertical part CPV of channel pattern CP CP in the second direction (or Y direction) may be 1:10 to 1:1. However, the present disclosure is not limited thereto, and the width of the gate insulating pattern 120 in the second direction (or Y direction) may be greater than the width of the vertical part CPV of the channel pattern CP in the second direction (or Y direction). For example, a ratio of the gate insulating pattern 120 to the channel pattern CP may be 1:1 to 1:1.5.

The semiconductor device according to example embodiments may further include the first insulating pattern 130, a second insulating pattern 140, and the third insulating pattern 160.

The first insulating pattern 130 may be disposed on the channel pattern CP and the lower insulating layer 110, and the first insulating pattern 130 may be disposed in the channel trench TRC. The first insulating pattern 130 may be disposed on the word lines WL1 and WL2 and above the channel pattern CP.

The first insulating pattern 130 may be in contact with the upper surface of the horizontal part CPH of the channel pattern CP. The first insulating pattern 130 may extend on the side surfaces of the word lines WL1 and WL2 and the upper surfaces of the word lines WL1 and WL2, and may be in contact with the side surfaces and upper surfaces of the word lines WL1 and WL2.

Like the gate insulating pattern 120, a portion of the first insulating pattern 130 may protrude more than the upper surfaces of the word lines WL1 and WL2 in the third direction (or Z direction) to be in contact with a portion of the gate insulating pattern 120 that protrudes more than the upper surfaces of the word lines WL1 and WL2 in the third direction (or Z direction).

The first insulating pattern 130 may include an insulating material. For example, the first insulating pattern 130 may include silicon nitride, silicon nitride oxide, or a combination thereof. However, the first insulating pattern 130 is not limited to including the above material, and may include various materials.

The second insulating pattern 140 may be disposed in the channel trench TRC. The second insulating pattern 140 may fill the channel trench TRC that remains after forming the channel pattern CP, the gate insulating pattern 120, the word lines WL1 and WL2, and the first insulating pattern 130.

That is, the second insulating pattern 140 may include a horizontal part and a vertical part. The vertical part of the second insulating pattern 140 may extend from the horizontal part of the second insulating pattern 140 toward the bit line BL in the third direction (or Z direction). The vertical part of the second insulating pattern 140 may be closer to the bit line BL than the horizontal part of the second insulating pattern 140.

The horizontal part of the second insulating pattern 140 may be disposed on the upper surfaces of word lines WL1 and WL2, and the vertical part of the second insulating pattern 140 may be disposed above the bit line BL. Accordingly, the second insulating pattern 140 may have a substantially “T” shape in the cross-section. However, the second insulating pattern 140 is not limited to this cross-sectional shape, and may have various other modifications.

The second insulating pattern 140 may include an insulating material. For example, the second insulating pattern 140 may include silicon oxide. However, the present disclosure is not limited thereto, and the second insulating pattern 140 may include the same material as the first insulating pattern 130 described above.

The third insulating pattern 160 may be disposed on the second insulating pattern 140 and the first insulating pattern 130. The third insulating pattern 160 may include the same material as the first insulating pattern 130. For example, the third insulating pattern 160 may include silicon nitride, silicon nitride oxide, or a combination thereof. However, the third insulating pattern 160 is not limited to including the above material, and the third insulating pattern 160 may include the same material as the above-mentioned second insulating pattern.

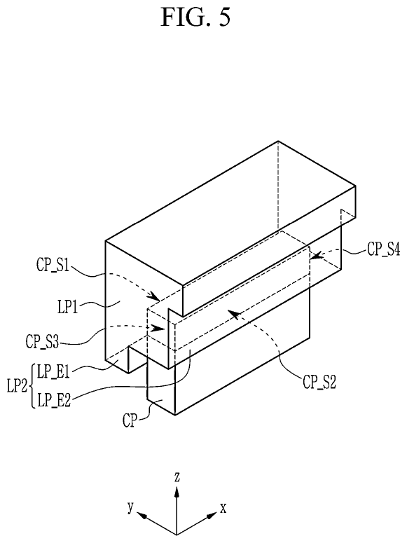

Hereinafter, the description describes the landing pad LP of the semiconductor device according to example embodiments with further reference to FIGS. 5 and 6.

FIGS. 5 and 6 are perspective views each showing the landing pad of the semiconductor device according to example embodiments.

Further referring to FIGS. 5 and 6, the landing pad LP may overlap at least a portion of the channel pattern CP in the third direction (or Z direction) which is the vertical direction. As shown in FIG. 1, the landing pads LP may be arranged in a matrix form and spaced apart from each other in the first direction (or X direction) and the second direction (or Y direction). However, this configuration is only an example, and the plurality of landing pads LP may be arranged in various other forms, such as a honeycomb form, as long as the landing pad is connected to the channel pattern CP.

The landing pad LP may have various shapes such as a circular, elliptical, rectangular, square, rhombic, or hexagonal shape on a plane. However, the planar shape of the landing pad LP is not limited thereto. Hereinafter, the description describes a case where that landing pad LP has the rectangular shape on a plan.

The landing pad LP may be disposed on the first interlayer insulating layer 210, the channel pattern CP, the gate insulating pattern 120, and the third insulating pattern 160. The landing pad LP may be electrically connected to the channel pattern CP. The landing pad LP may penetrate through an upper insulating layer 150 to be in contact with the upper surface and side surface of the channel pattern CP.

The landing pad LP may include doped polysilicon, metal, conductive metal nitride, conductive metal silicide, conductive metal oxide, or a combination thereof. For example, the landing pad LP may include aluminum (AI), copper (Cu), titanium (Ti), tantalum (Ta), ruthenium (Ru), tungsten (W), molybdenum (Mo), platinum (Pt), nickel (Ni), cobalt (Co), titanium nitride (TiN), tantalum nitride (TaN), tungsten nitride (WN), niobium nitride (NbN), titanium aluminum (TiAl), titanium aluminum nitride (TiAlN), titanium silicide (TiSi), titanium silicide nitride (TiSiN), tantalum silicate (TaSi), tantalum silicon nitride (TaSiN), ruthenium titanium nitride (RuTiN), nickel-silicide (NiSi), cobalt monosilicide (CoSi), iridium oxide (IrOx), ruthenium oxide (RuOx), or a combination thereof, and is not limited thereto.

The landing pad LP may include a first part LP1 in contact with the upper surface of the channel pattern CP and a second part LP2 protruding from a lower surface of the first part LP1 in the third direction (or Z direction). The second part LP2 may include a first protrusion LP_E1 and a second protrusion LP_E2.

The first part LP1 of the landing pad LP may be disposed on the first interlayer insulating layer 210, the channel pattern CP, the gate insulating pattern 120, the first insulating pattern 130, and the third insulating pattern 160. The first part LP1 may overlap at least a part of the channel pattern CP in the third direction (or Z direction). The first part LP1 may be in contact with the channel pattern CP. For example, a portion of the bottom surface of the first part LP1 may be in contact with the upper surface of the channel pattern CP. Here, the first part LP1 may be a portion of the landing pad LP in which the landing pad LP does not overlap the channel pattern CP in the second direction (or Y direction).

The first protrusion LP_E1 may protrude from the lower surface of the first part LP1 in the third direction (or Z direction). For example, the first protrusion LP_E1 may extend from the lower surface of the first part LP1 along the first surface CP_S1 of the channel pattern CP. The first protrusion LP_E1 may overlap the first interlayer insulating layer 210 in the vertical direction (e.g., third direction (or Z direction)). The first protrusion LP_E1 may be disposed between the second interlayer insulating layer 220 and the channel pattern CP.

Here, the first surface CP_S1 of the channel pattern CP may be a surface in contact with the first protrusion LP_E1, and the second surface CP_S2 may be a surface opposite to the first surface CP_S1. The third surface CP_S3 may be a surface connected to the first surface CP_S1 and the second surface CP_S2, and the fourth surface CP_S4 may be a surface opposite to the third surface CP_S3. The first to fourth surfaces CP_S1 to CP_S4 of the channel pattern CP may be the side surfaces of the channel pattern CP that are surrounded by the landing pad LP.

The first protrusion LP_E1 may be surrounded by a side surface of the second interlayer insulating layer 220, the upper surface of the first interlayer insulating layer 210, and the first surface CP_S1 of the channel pattern CP. That is, one surface of the first protrusion LP_E1 may overlap the channel pattern CP in the second direction (or Y direction), and the other surface of the first protrusion LP_E1 may overlap the second interlayer insulating layer 220 in the second direction (or Y direction). A bottom surface of the first protrusion LP_E1 may overlap the first interlayer insulating layer 210 in the third direction (or Z direction).

As the first protrusion LP_E1 protrudes from the lower surface of the first part LP1 in the third direction (or Z direction), the first protrusion LP_E1 may overlap the channel pattern CP in the second direction (or Y direction). In detail and for example, a side surface of the first protrusion LP_E1 may overlap the first surface CP_S1 of the channel pattern CP in the second direction (or Y direction). The bottom surface of the first protrusion LP_E1 may be disposed at a lower level than the upper surface of the channel pattern CP. The first protrusion LP_E1 may be in contact with a portion of the first surface CP_S1 of the channel pattern CP. That is, the landing pad LP may be connected to the channel pattern CP through the first protrusion LP_E1.

A portion of the first protrusion LP_E1 may overlap the word line WL1 or WL2 in the second direction (or Y direction). That is, the bottom surface of the first protrusion LP_E1 may be disposed at a lower level than that of the upper surface of the word line WL1 or WL2. In this case, a portion of the channel pattern CP may overlap the first protrusion LP_E1 and the word line WL1 or WL2 in the second direction (or Y direction). Accordingly, an internal resistance of the channel pattern CP or a parasitic resistance formed between one end of the channel pattern CP (e.g., second source/drain region of the channel pattern CP) and the word line WL1 or WL2 may be lower to improve a characteristic of the semiconductor device. However, the present disclosure is not limited thereto, and the first protrusion LP_E1 may not overlap the word line WL1 or WL2 in the second direction (or Y direction).

A width of the first protrusion LP_E1 in the second direction (or Y direction) may be greater than a width of the channel pattern CP in the second direction (or Y direction), and is not limited thereto.

Due to the provided first protrusion LP_E1, a length of a portion of the landing pad LP in the third direction (or Z direction), which overlaps the first interlayer insulating layer 210 in the third direction (or Z direction) may be longer than a length of a portion of the landing pad LP in the third direction (or Z direction), which overlaps the channel pattern CP in the third direction (or Z direction).

The second protrusion LP_E2 may protrude from the lower surface of the first part LP1 in the third direction (or Z direction). For example, the second protrusion LP_E2 may extend from the lower surface of the first part LP1 along the second surface CP_S2 of the channel pattern CP. The second protrusion LP_E2 may overlap the gate insulating pattern 120 in the vertical direction (e.g., third direction (or Z direction)). The second protrusion LP_E2 may be disposed between the channel pattern CP and the first insulating pattern 130.

The second protrusion LP_E2 may be surrounded by a side surface of the first insulating pattern 130, the upper surface of the gate insulating pattern 120, and the second surface CP_S2 of the channel pattern CP. That is, one surface of the second protrusion LP_E2 may overlap the channel pattern CP in the second direction (or Y direction) (e.g., a horizontal direction), and the other surface of the second protrusion LP_E2 may overlap the first insulating pattern 130 in the second direction (or Y direction). A bottom surface of the second protrusion LP_E2 may overlap the gate insulating pattern 120 in the third direction (or Z direction).

As the second protrusion LP_E2 protrudes from the lower surface of the first part LP1 in the third direction (or Z direction), the second protrusion LP_E2 may overlap the channel pattern CP in the second direction (or Y direction). In detail and for example, a side surface of the second protrusion LP_E2 may overlap the second surface CP_S2 of the channel pattern CP in the second direction (or Y direction). The second protrusion LP_E2 may be in contact with the second surface CP_S2 of the channel pattern CP. The bottom surface of the second protrusion LP_E2 may be disposed at a lower level than the upper surface of the channel pattern CP

As shown in FIGS. 3 and 5, the second protrusion LP_E2 may overlap the channel pattern CP in the first direction (or X direction). In detail and for example, the side surface of the second protrusion LP_E2 may overlap the third surface CP_S3 and fourth surface CP_S4 of the channel pattern CP. That is, a portion of the channel pattern CP may be disposed between the second protrusions LP_E2. The side surface of the second protrusion LP_E2 may be in contact with the third surface CP_S3 and fourth surface CP_S4 of the channel pattern CP. That is, the landing pad LP may be connected to the channel pattern CP through the second protrusion LP_E2.

The second protrusion LP_E2 may not overlap the word line WL1 or WL2 in the second direction (or Y direction). That is, the bottom surface of the second protrusion LP_E2 may be disposed at a higher level than that of the upper surface of the word line WL1 or WL2. The bottom surface of the second protrusion LP_E2 may be farther from the upper surface of the substrate 100 than the upper surface of the word line WL1 or WL2. Therefore, the second protrusion LP_E2 may be spaced apart from the word line WL1 or WL2 to prevent the second protrusion LP_E2 from being shorted from the word line WL1 or WL2.

As shown in FIG. 4, a length of the second protrusion LP_E2 in the third direction (or Z direction) may be different from a length of the first protrusion LP_E1 in the third direction (or Z direction). For example, a second length W2 of the second protrusion LP_E2 in the third direction (or Z direction) may be smaller than a first length W1 of the first protrusion LP_E1 in the third direction (or Z direction), and is not limited thereto. That is, the bottom surface of the second protrusion LP_E2 may be disposed at a higher level than that of the bottom surface of the first protrusion LP_E1. The bottom surface of the second protrusion LP_E2 may be farther from the upper surface of the substrate 100 than the bottom surface of the first protrusion LP_E1.

A length of the first surface CP_S1 of the channel pattern CP, which overlaps the first protrusion LP_E1 in the second direction (or Y direction), may be substantially the same as the first length of the first protrusion LP_E1 in the third direction (or Z direction). A length of the second surface CP_S2 of the channel pattern CP, which overlaps the second protrusion LP_E2 in the second direction (or Y direction), may be substantially the same as the second length of the second protrusion LP_E2 in the third direction (or Z direction). Therefore, a contact area of the channel pattern CP with the first protrusion LP_E1 may be larger than a contact area of the channel pattern CP with the second protrusion LP_E2.

A width of the second protrusion LP_E2 in the second direction (or Y direction) may be substantially the same as a width of the gate insulating pattern 120 in the second direction (or Y direction). The width of the second protrusion LP_E2 in the second direction (or Y direction) may be smaller than the width of the first protrusion LP_E1 in the second direction (or Y direction), and is not limited thereto.

Due to the provided second protrusion LP_E2, a length of a portion of the landing pad LP in the third direction (or Z direction), which overlaps the gate insulating pattern 120 in the third direction (or Z direction) may be longer than a length of a portion of the landing pad LP in the third direction (or Z direction), which overlaps the channel pattern CP in the third direction (or Z direction). A length of a portion of the landing pad LP in the third direction (or Z direction), which overlaps the gate insulating pattern 120 in the third direction (or Z direction) may be shorter than a length of a portion of the landing pad LP in the third direction (or Z direction), which overlaps the first interlayer insulating layer 210 in the third direction (or Z direction).

In summary, as shown in FIGS. 5 and 6, the first protrusion LP_E1 and the second protrusion LP_E2 may surround the four side surfaces of one end of the channel pattern CP. The first part LP1 may cover the upper surface of the channel pattern CP. Accordingly, one end of the channel pattern CP may be surrounded by the first protrusion LP_E1 and the second protrusion LP_E2. The channel pattern CP may penetrate into the lower surface of the landing pad LP. The channel pattern CP may fill the inside of the recess LP_R of the landing pad that is concave from the lower surface of the landing pad LP.

The contact area between the channel pattern CP and the landing pad LP may be larger as the channel pattern CP is surrounded by the first protrusion LP_E1 and the second protrusion LP_E2. Accordingly, the contact resistance between the channel pattern CP and the landing pad LP may be lower, thus improving reliability of the semiconductor memory device.

The semiconductor device according to example embodiments may further include the upper insulating layer 150 and data storage patterns DSP.

The upper insulating layer 150 may be disposed on the third insulating pattern 160. The upper insulating layer 150 may fill a space between the landing pads LP spaced apart from each other in the second direction (or Y direction).

The data storage pattern DSP may be disposed on each landing pad LP. Each data storage pattern DSP may be electrically connected to the channel pattern CP through the landing pad LP. As shown in FIG. 1, the data storage patterns DSP may be arranged in a matrix form in the first direction (or X direction) and the second direction (or Y direction).

In example embodiments, the data storage pattern DSP may be a capacitor, and include a capacitor dielectric layer interposed between lower and upper electrodes. In the case where the data storage patterns DSP has the above structure, the lower electrode may be in contact with the landing pad LP, and the lower electrode may have any of various shapes such as a circular, elliptical, rectangular, square, rhombic, hexagonal shape, or the like on a plane.

Alternatively, the data storage pattern DSP may be a variable resistance pattern that may be switched into two resistance states by an electrical pulse applied to a memory element. For example, the data storage pattern DSP may include a phase-change material whose crystal state is changed based on an amount of a current, a perovskite compound, a transition metal oxide, a magnetic material, a ferromagnetic material, or an antiferromagnetic material.

The channel pattern CP of the semiconductor device according to example embodiments may be connected to the landing pad LP. Here, the contact resistance between the channel pattern CP and the landing pad LP may be determined based on the contact area between the channel pattern CP and the landing pad LP. For example, the larger contact area between the channel pattern CP and the landing pad LP, the lower contact resistance between the channel pattern CP and the landing pad LP.

The landing pad LP of the semiconductor device according to example embodiments may include the first protrusion LP_E1 and the second protrusion LP_E2, and the landing pad LP may thus surround one end of the channel pattern CP. Accordingly, the contact area between the channel pattern CP and the landing pad LP may be larger. Accordingly, the contact resistance between the channel pattern CP and the landing pad LP may be lower, thus improving the reliability of the semiconductor memory device.

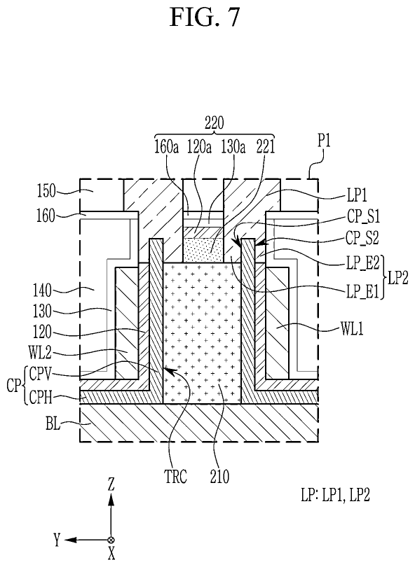

Hereinafter, the description describes a semiconductor device according to example embodiments with reference to FIGS. 7 to 10.

FIG. 7 is an enlarged cross-sectional view corresponding to the region P1 of FIG. 2, showing a semiconductor device according to example embodiments.

The embodiment shown in FIG. 7 has some parts substantially the same as those of the embodiments shown in FIGS. 1 through 6, and the description thus omits descriptions thereof and mainly describes its difference. A shape of a first protrusion LP_E1 of a landing pad LP in FIG. 7 is different from that in FIGS. 1-6, and is described below

A cell array structure of the semiconductor device according to example embodiments may include a substrate 100, a lower insulating layer 110 disposed on the substrate 100, a bit line BL, a channel pattern CP disposed on the bit line BL, a word line WL1 or WL2 disposed on the channel pattern CP, a gate insulating pattern 120 disposed between the channel pattern CP and the word lines WL1 and WL2, and a landing pad LP electrically connected to the channel pattern CP.

In example embodiments such as shown in FIG. 7, the length of the second protrusion LP_E2 in a third direction (or Z direction) may be different from the length of the first protrusion LP_E1 in the third direction (or Z direction). For example, similar as to shown in FIG. 4, the second length W2 of the second protrusion LP_E2 in the third direction (or Z direction) may be smaller than the first length W1 of the first protrusion LP_E1 in the third direction (or Z direction).

Referring to FIG. 7, a length of the first protrusion LP_E1 of the landing pad LP of the semiconductor device according to example embodiments may be substantially the same as a length of the second protrusion LP_E2 in the third direction (or Z direction). That is, a bottom surface of the first protrusion LP_E1 may be disposed at substantially the same level as that of the bottom surface of the second protrusion LP_E2. In the specification, “same” may indicate not only the completely or exactly the same thing, but also the same thing including a subtle difference that may occur due to a margin in a process.

The first protrusion LP_E1 may not overlap the word line WL1 or WL2 in a second direction (or Y direction). That is, the bottom surface of the first protrusion LP_E1 may be disposed at a higher level than that of an upper surface of the word line WL1 or WL2.

Accordingly, a length of a portion of the landing pad LP in the third direction (or Z direction), which overlaps the gate insulating pattern 120 in the third direction (or Z direction) may be substantially the same as a length of a portion of the landing pad LP in the third direction (or Z direction), which overlaps the first interlayer insulating layer 210 in the third direction (or Z direction).

An upper surface of the first interlayer insulating layer 210 may be disposed at substantially the same level as that of an upper surface of the gate insulating pattern 120. That is, the upper surface of the first interlayer insulating layer 210 may be disposed at substantially the same level as that of the upper surface of the gate insulating pattern 120 and an upper surface of the substrate 100. However, even in this case, the upper surface of the first interlayer insulating layer 210 may be disposed at a lower level than that of an upper surface of the channel pattern CP.

However, even in the case of the semiconductor device according to example embodiments, one end of the channel pattern CP may be surrounded by the first protrusion LP_E1 and the second protrusion LP_E2. The channel pattern CP may penetrate into a lower surface of the landing pad LP. The channel pattern CP may fill the inside of a recess LP_R of the landing pad that is concave from the lower surface of the landing pad LP.

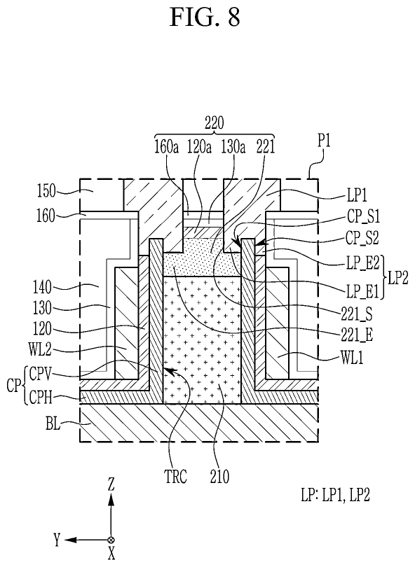

FIG. 8 is an enlarged cross-sectional view corresponding to the region P1 of FIG. 2, showing the semiconductor device according to example embodiments.

The embodiment shown in FIG. 8 has some parts substantially the same as those embodiments shown in FIGS. 1 through 6, and the description thus omits descriptions thereof and mainly describes its difference. A shape of a first protrusion LP_E1 of a landing pad LP and a shape of a first layer 221 of a second interlayer insulating layer 220 in FIG. 8 are different from those in FIG. 4 for example, and is described below.

A cell array structure of the semiconductor device according to example embodiments may include a substrate 100, a lower insulating layer 110 disposed on the substrate 100, a bit line BL, a channel pattern CP disposed on the bit line BL, word lines WL1 and WL2 disposed on the channel pattern CP, a gate insulating pattern 120 disposed between the channel pattern CP and the word lines WL1 and WL2, and a landing pad LP electrically connected to the channel pattern CP.

In example embodiments such as shown in FIG. 4 for example, a width of the second interlayer insulating layer 220 in a second direction (or Y direction) may be smaller than a width of the first interlayer insulating layer 210 in the second direction. Accordingly, the channel patterns CP may not be in contact with the second interlayer insulating layer 220. A bottom surface of the first protrusion LP_E1 of the landing pad LP may be in contact with an upper surface of the first interlayer insulating layer 210.

Referring to FIG. 8, the second interlayer insulating layer 220 of the semiconductor device according to example embodiments may include an extension 221_E extending in the second direction (or Y direction). For example, the first layer 221 of the second interlayer insulating layer 220 may include the extension 221_E extending from a side surface 221_S of the first layer 221 in the second direction (or Y direction). The extension 221_E may extend from the side surface 221_S of the first layer 221 along the upper surface of the first interlayer insulating layer 210. Accordingly, a width of a lower surface of the first layer 221 in the second direction (or Y direction) may be greater than a width of the upper surface of the first layer 221 in the second direction (or Y direction). That is, a width of a lower surface of the second interlayer insulating layer 220 in the second direction (or Y direction) may be greater than a width of the upper surface of the second interlayer insulating layer 220 in the second direction (or Y direction).

The landing pad LP may be disposed on the second interlayer insulating layer 220. For example, the first protrusion LP_E1 of the landing pad LP may be disposed on an upper surface of the extension 221_E and a side surface of the second interlayer insulating layer 220. Accordingly, the first protrusion LP_E1 of the landing pad LP may not be in contact with the first interlayer insulating layer 210.

However, even in this case, the first protrusion LP_E1 of the landing pad LP may overlap a first surface CP_S1 of the channel pattern CP in the second direction (or Y direction). A second protrusion LP_E2 may overlap a second surface CP_S2 of the channel pattern CP in the second direction (or Y direction). Therefore, one end of the channel pattern CP may be surrounded by the landing pad LP.

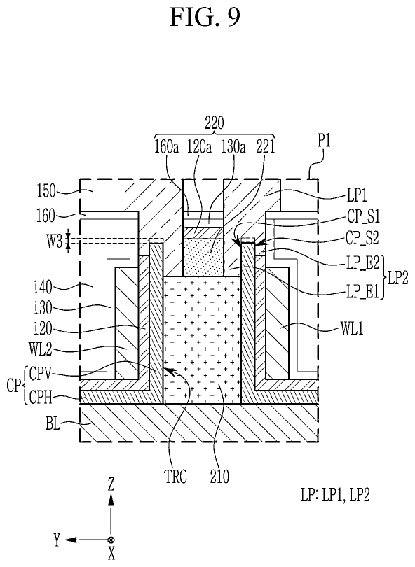

FIG. 9 is an enlarged cross-sectional view corresponding to the region P1 of FIG. 2, showing a semiconductor device according to example embodiments.

The embodiment shown in FIG. 9 has some parts substantially the same as those of the embodiments shown in FIGS. 1 through 6, and the description thus omits descriptions thereof and mainly describes its difference. A height of one end of a channel pattern CP in FIG. 9 is different from that in FIG. 4 for example, and is described below.

A cell array structure of the semiconductor device according to example embodiments may include a substrate 100, a lower insulating layer 110 disposed on the substrate 100, a bit line BL, the channel pattern CP disposed on the bit line BL, word lines WL1 and WL2 disposed on the channel pattern CP, a gate insulating pattern 120 disposed between the channel pattern CP and the word lines WL1 and WL2, and a landing pad LP electrically connected to the channel pattern CP.

In example embodiments such as shown in FIG. 4 for example, an upper surface of the channel pattern CP may be disposed at substantially the same level as that of an upper surface of the first layer 221 of a second interlayer insulating layer 220. That is, the upper surface of the channel pattern CP may be disposed at substantially the same level as that of a lower surface of a second layer 120a of the second interlayer insulating layer 220. That is, the upper surface of the channel pattern CP may be disposed at substantially the same level as that of the lower surface of the second layer 120a of the second interlayer insulating layer 220 and that of the upper surface of the substrate 100.

Referring to FIG. 9, the upper surface of the channel pattern CP of the semiconductor device according to example embodiments may be disposed at a lower level than the upper surface of the first layer 221 of the second interlayer insulating layer 220. The upper surface of the channel pattern CP may be disposed at a lower level than that of the lower surface of the second layer 120a of the second interlayer insulating layer 220. For example, the upper surface of the channel pattern CP may be disposed at a lower level than that of the upper surface of the first layer 221 of the second interlayer insulating layer 220 by a third width W3. This configuration may be possible due to a characteristic of an etching process in which at least a portion of the upper surface of the channel pattern CP is etched together in a process of etching a portion of the gate insulating pattern 120. Alternatively, this configuration may be possible due to a separate process of etching at least a portion of the upper surface of the channel pattern CP. However, even in this case, the upper surface of the channel pattern CP may be disposed at a higher level than an upper surface of the gate insulating pattern 120.

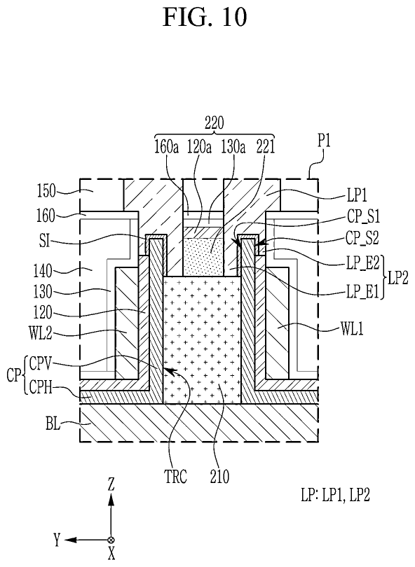

FIG. 10 is an enlarged cross-sectional view corresponding to the region P1 of FIG. 2, showing a semiconductor device according to example embodiments.

The embodiment shown in FIG. 10 has some parts substantially the same as those of example embodiments shown in FIGS. 1 through 6, and the description thus omits descriptions thereof and mainly describes its difference. FIG. 10 is different from FIG. 4 for example in further including a silicide film SI on one end of a channel pattern CP, which is described below.

A cell array structure of the semiconductor device according to example embodiments may include a substrate 100, a lower insulating layer 110 disposed on the substrate 100, a bit line BL, the channel pattern CP disposed on the bit line BL, word lines WL1 and WL2 disposed on the channel pattern CP, a gate insulating pattern 120 disposed between the channel pattern CP and the word lines WL1 and WL2, and a landing pad LP electrically connected to the channel pattern CP.

In example embodiments such as shown in FIG. 4 for example, a first surface CP_S1 of the channel pattern CP may be in contact with a first protrusion LP_E1 of the landing pad LP, and the second to fourth surfaces CP_S2 to CP_S4 of the channel pattern CP may be in contact with a second protrusion LP_E2 of the landing pad LP. In this case, the channel pattern CP may include an oxide semiconductor material.

Referring to FIG. 10, the semiconductor device according to example embodiments may further include the silicide film SI disposed between the channel pattern CP and the landing pad LP.

The silicide film SI may be disposed on one end of the channel pattern CP. The silicide film SI may conformally cover the surface CP_S1, second surface CP_S2, and upper surface of the channel pattern CP. The silicide film SI may extend along a profile of one end of the channel pattern CP, and have an approximately “n” shape in the cross-section. Although not shown, the silicide film SI may be disposed on the third surface CP_S3 and fourth surface CP_S4 of the channel pattern CP (e.g., see FIG. 5). Accordingly, one end of the channel pattern CP may be surrounded by the silicide film SI. In this case, the channel pattern CP may include silicon, germanium, silicon-germanium, or a combination thereof.

The silicide film SI may include metal-silicide. For example, the silicide film SI may include at least one of titanium-silicide, tantalum-silicide, tungsten-silicide, nickel-silicide, and cobalt-silicide, and is not limited thereto.

One surface of the first protrusion LP_E1 of the landing pad LP may overlap the silicide film SI. The first protrusion LP_E1 may extend from a lower surface of a first part LP1 along one surface of the silicide film SI. The first protrusion LP_E1 may be disposed between a second interlayer insulating layer 220 and the silicide film SI. One surface of the second protrusion LP_E2 of the landing pad LP may overlap the silicide film SI. The second protrusion LP_E2 may extend from the lower surface of the first part LP1 along the other surface of the silicide film SI. The second protrusion LP_E2 may be disposed between a first insulating pattern 130 and the silicide film SI.

Even in the case of the semiconductor device according to example embodiments of FIG. 10, the landing pad LP may include the first protrusion LP_E1 and the second protrusion LP_E2, and the landing pad LP may thus surround one end of the channel pattern CP. Accordingly, a contact area between the channel pattern CP and the silicide film SI and a contact area between the silicide film SI and the landing pad LP may respectively be larger. Accordingly, a contact resistance between the channel pattern CP and the landing pad LP may be lower, thus improving reliability of the semiconductor memory device.

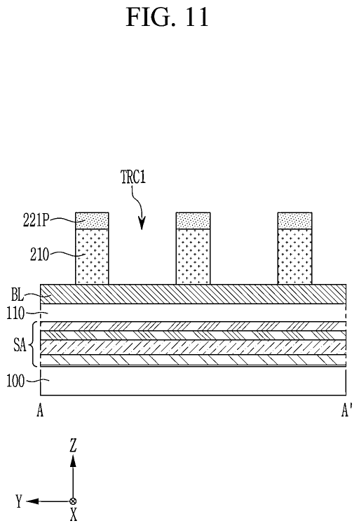

Hereinafter, the description describes a method for fabricating a semiconductor device with reference to FIGS. 11 through 22. Hereinafter, the same reference numerals refer to the same components previously described, and redundant descriptions are omitted or simplified, and the differences are mainly described.

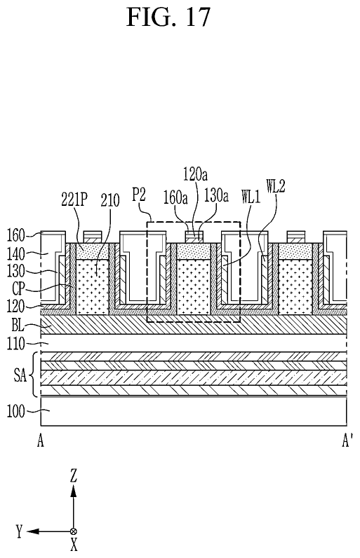

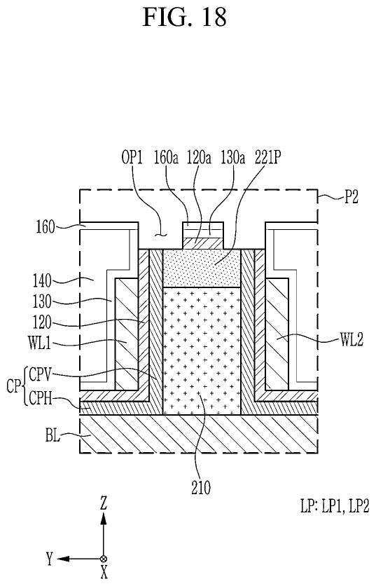

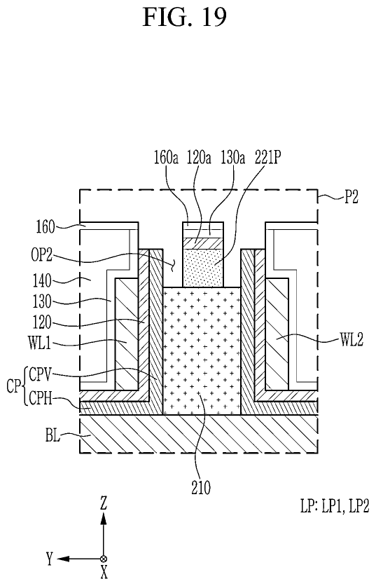

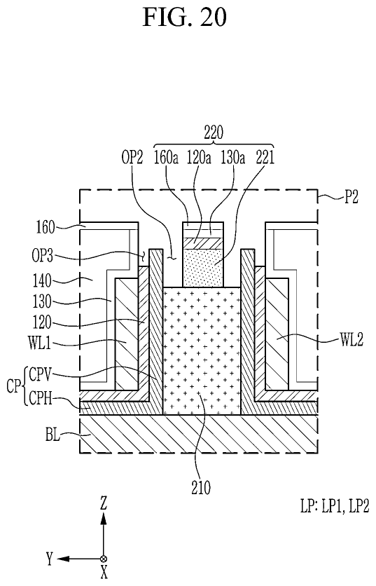

FIGS. 11 to 17, 21 and 22 are cross-sectional views each showing a method for fabricating a semiconductor device according to example embodiments. FIG. 18 is an enlarged cross-sectional view showing a region P2 of FIG. 17; and FIGS. 19 and 20 are enlarged cross-sectional views corresponding to the region P2 of FIG. 17, each showing a method for fabricating a semiconductor device according to still other example embodiments.

First, as shown in FIG. 11, n-channel metal-oxide semiconductor (nMOS) and p-channel metal-oxide semiconductor (pMOS) transistors may be formed on a substrate 100 as a core and peripheral circuits SA. Peripheral circuit wires and peripheral circuit contact plugs may be formed to be electrically connected to the core and the peripheral circuits SA.

Next, a lower insulating layer 110 may be formed on the substrate 100 to cover the core and the peripheral circuits SA, the peripheral circuit wires, and the peripheral circuit contact plugs. The lower insulating layer 110 may include multi-layered insulating films. For example, the lower insulating layer 110 may include a silicon oxide film, a silicon nitride film, a silicon nitride oxide film, or a low-k film.

Next, bit lines BL disposed on the lower insulating layer 110 may be formed, extending in a second direction (or Y direction), and spaced apart from each other in a first direction (or X direction), and a space between the bit lines BL may be filled with an insulating material. The bit line BL may be formed by depositing a conductive layer on the lower insulating layer 110 and then patterning the conductive layer.

Next, a first interlayer insulating layer 210 and a second interlayer insulating material layer 221P may be formed, disposed on the bit lines BL, extending in the first direction (or X direction), and defining first trenches TRC1 spaced apart from each other in the second direction (or Y direction). The first interlayer insulating layer 210 and the second interlayer insulating material layer 221P may be formed by depositing a material layer on the bit line BL and then patterning the material layer.

The first trench TRC1 may be disposed across the bit line BL. The first interlayer insulating layer 210 may be, for example, a silicon oxide film. The second interlayer insulating material layer 221P may include a silicon nitride film, a silicon nitride oxide film, or a low-k film.

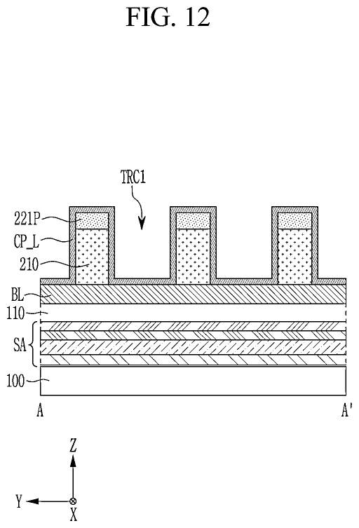

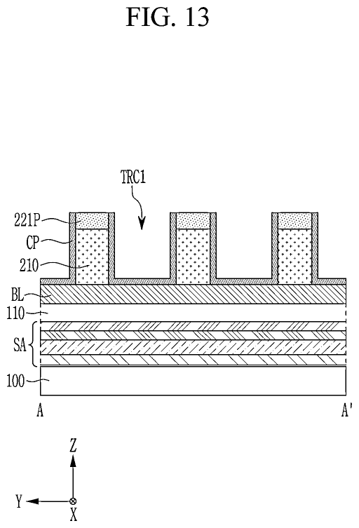

As shown in FIGS. 12 and 13, a channel pattern material layer CP_L may be conformally deposited on an upper surface of the second interlayer insulating material layer 221P, side surfaces of the first interlayer insulating layer 210 and second interlayer insulating material layer 221P, and an upper surface of the bit line BL.

The channel pattern material layer CP_L may be formed using at least one of physical vapor deposition (PVD), thermal chemical vapor deposition (thermal CVD), low pressure chemical vapor deposition (LP-CVD), plasma enhanced chemical vapor deposition (PE-CVD) or atomic layer deposition (ALD) methods. However, the method of depositing the channel pattern material layer CP_L is not limited thereto and may be variously changed.

The channel pattern material layer CP_L may include a semiconductor material, an oxide semiconductor material, or a two-dimensional semiconductor material. The channel pattern material layer CP_L may include, for example, silicon, germanium, silicon-germanium, or indium gallium zinc oxide (IGZO).

Next, a channel pattern CP may be formed in the first trench TRC1 by patterning the channel pattern material layer CP_L.

In detail and for example, the upper surface of the second interlayer insulating material layer 221P may be exposed by forming a sacrificial pattern filling the first trench TRC1 in the first trench TRC1, and then patterning the channel pattern material layer CP_L disposed on the upper surface of the second interlayer insulating material layer 221P.

Accordingly, the channel pattern CP may be formed along a profile of the first trench TRC1, and an upper surface of the channel pattern CP may be disposed at substantially the same level as that of the upper surface of the second interlayer insulating material layer 221P.

The channel pattern CP may be a portion of the channel pattern material layer CP_L that remains in the first trench TRC1 while the channel pattern material layer CP_L is patterned. However, the process of forming the channel pattern CP is not limited thereto. For example, the channel pattern CP may be formed by forming the sacrificial pattern filling the first trench TRC1, and then performing a planarization process exposing the upper surface of the second interlayer insulating material layer 221P.

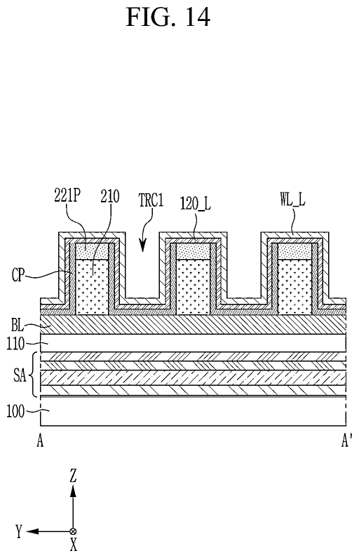

As shown in FIG. 14, a gate insulating pattern material layer 120_L that conformally covers the second interlayer insulating material layer 221P and the channel pattern CP, and a word line material layer WL_L may be sequentially deposited.

The gate insulating pattern material layer 120_L and the word line material layer WL_L may each be formed using at least one of physical vapor deposition (PVD), thermal chemical vapor deposition (thermal CVD), low pressure chemical vapor deposition (LP-CVD), plasma enhanced chemical vapor deposition (PE-CVD) or atomic layer deposition (ALD) methods. However, the method of depositing the gate insulating pattern material layer 120_L and the word line material layer WL_L is not limited thereto, and may be variously changed.

The gate insulating pattern material layer 120_L may include aluminum oxide (Al₂O₃), silicon oxide (SiO₂), a low-k material having a lower dielectric constant than silicon oxide (SiO₂), or a combination thereof.

The word line material layer WL_L may include doped polysilicon, metal, conductive metal nitride, conductive metal silicide, conductive metal oxide, or a combination thereof.

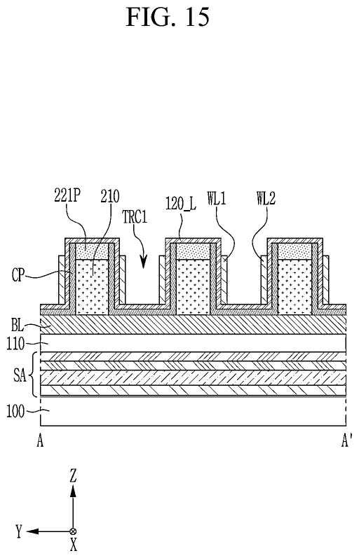

As shown in FIG. 15, the word lines WL1 and WL2 may be formed in the first trench TRC1 by performing an etching process on the word line material layer WL_L.

That is, the pair of first word lines WL1 and WL2 may be formed separated from each other by being spaced apart from each other in the first trench TRC1 in the second direction (or Y direction) by performing the etching process on the word line material layer WL_L. The word line WL1 or WL2 may be a portion of the word line material layer WL_L that remains in the first trench TRC1 while the word line material layer WL_L is etched.

In example embodiments, an etching process for recessing upper surfaces of the word lines WL1 and WL2 during the etching process of the word line material layer WL_L may additionally be performed. Accordingly, the upper surface of the word line WL1 or WL2 may be disposed at a level lower than that of the upper surface of the second interlayer insulating material layer 221P or that of the upper surface of the channel pattern CP. That is, the upper surface of the word line WL1 or WL2 may be disposed closer to an upper surface of the substrate 100 than the upper surface of the second interlayer insulating material layer 221P or the upper surface of the channel pattern CP.

In addition, in example embodiments, the etching process on the gate insulating pattern material layer 120_L may be performed simultaneously with the etching process of the word line material layer WL_L.

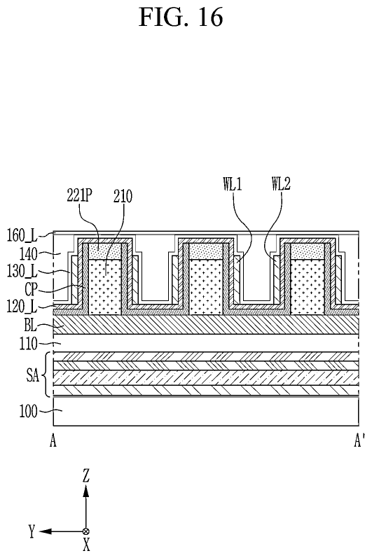

As shown in FIG. 16, a first insulating pattern material layer 130_L may be formed on the gate insulating pattern material layer 120_L and the word lines WL1 and WL2 that are disposed in the first trench TRC1, and a second insulating pattern 140 may be formed filling the first trench TRC1. A third insulating pattern material layer 160_L may be formed on the first insulating pattern material layer 130_L and the second insulating pattern 140.

In detail, the first insulating pattern material layer 130_L may be conformal on profiles of the gate insulating pattern material layer 120_L and the word lines WL1 and WL2 that are disposed in the first trench TRC1.

The first insulating pattern material layer 130_L may be formed using at least one of physical vapor deposition (PVD), thermal chemical vapor deposition (thermal CVD), low pressure chemical vapor deposition (LP-CVD), plasma enhanced chemical vapor deposition (PE-CVD) or atomic layer deposition (ALD) methods. However, the method of depositing a first insulating pattern 130 is not limited thereto, and may be variously changed.

Next, the second insulating pattern 140 may be formed filling the first trench TRC1 that remains after forming the first insulating pattern material layer 130_L, and then the third insulating pattern material layer 160_L may be formed on the first insulating pattern material layer 130_L and the second insulating pattern 140.

The process of forming the second insulating pattern 140 may include a planarization process of exposing an upper surface of the first insulating pattern material layer 130_L. That is, the second insulating pattern 140 may be a portion of the second insulating pattern 140 that remains in the first trench TRC1 after the planarization process is performed.

As shown in FIGS. 17 and 18, a first open part OP1 may be formed in an etching process for recessing portions of the third insulating pattern material layer 160_L, the first insulating pattern material layer 130_L, and the gate insulating pattern material layer 120_L.

In detail, the first open part OP1 extending in a third direction (or Z direction) may be formed by etching the corresponding portions of the third insulating pattern material layer 160_L, the first insulating pattern material layer 130_L, and the gate insulating pattern material layer 120_L from top to bottom. The first open part OP1 may expose the corresponding portions of the upper surface of the channel pattern CP, an upper surface of the gate insulating pattern 120, and the second interlayer insulating material layer 221P, and forms the second layer 120a, the third layer 130a, and the fourth layer 160a.

Accordingly, it is possible to form a third insulating pattern 160, the first insulating pattern 130, and a gate insulating pattern 120.

As shown in FIG. 19, a second open part OP2 may be formed by etching an exposed portion of the second interlayer insulating material layer 221P.

In detail, an etching process may be performed to remove the exposed portion of the second interlayer insulating material layer 221P. The etching process may be performed by, for example, a wet etching method, and is not limited thereto. The exposed portion of the second interlayer insulating material layer 221P may be removed by performing an etching process on the first interlayer insulating layer 210 with an etchant having higher etch selectivity.

Accordingly, the second open part OP2 may be formed. A lower surface of the second open part OP2 may be defined by the first interlayer insulating layer 210, and sidewalls of the second open part OP2 may be defined by the channel pattern CP and a second interlayer insulating layer 220. The second open part OP2 may expose a portion of an upper surface of the first interlayer insulating layer 210 and a portion of a side surface of the channel pattern CP. The second interlayer insulating layer 220 may be formed by the second open part OP2.

In example embodiments, the removal process of the exposed portion of the second interlayer insulating material layer 221P is not limited thereto, and may be variously changed. For example, the exposed portion of the second interlayer insulating material layer 221P may be etched to reduce a thickness of the second interlayer insulating material layer 221P in the third direction (or Z direction). In this case, a lower surface of the second open part OP2 may be defined by the second interlayer insulating layer 220. That is, the first interlayer insulating layer 210 may not be exposed.

As shown in FIG. 20, a third open part OP3 may be formed by etching the exposed portion of the gate insulating pattern 120.

In detail, the exposed portion of the gate insulating pattern 120 may be removed by performing an etching process. The etching process may be performed by, for example, a wet etching method, and is not limited thereto. The exposed portion of the gate insulating pattern 120 may be removed by performing the etching process on the channel pattern CP, the third insulating pattern 160, and the first insulating pattern 130 with an etchant with higher etch selectivity. In example embodiments, the etching process may be performed on the first interlayer insulating layer 210 with an etchant having higher etch selectivity.

Accordingly, the third open part OP3 may be formed. A lower surface of the third open portion OP3 may be defined by the gate insulating pattern 120, and sidewalls of the third open portion OP3 may be defined by the channel pattern CP and the first insulating pattern 130. The third open portion OP3 may expose portions of the upper surface of the gate insulating pattern 120, the side surface of the channel pattern CP, and a side surface of the first insulating pattern 130.

A bottom surface of the third open part OP3 may be disposed at a lower level than that of a bottom surface of the second open part OP2. For example, the bottom surface of the second open part OP2 may be disposed at a level higher than that of the upper surfaces of the word lines WL1 and WL2, and the bottom surface of the third open part OP3 may be disposed at a higher level than that of the upper surfaces of the word lines WL1 and WL2. Accordingly, an area of the side surface of the channel pattern CP that is exposed by the third open part OP3 (or its length in the third direction (or Z direction)) may be greater than an area of the side surface of the channel pattern CP that is exposed by the second open part OP2 (or its length in the third direction (or Z direction)).

In example embodiments, a portion of the channel pattern CP may be etched together in the process of forming the third open portion OP3 by etching the exposed portion of the gate insulating pattern 120. For example, the length of the channel pattern CP in the third direction (or Z direction) may be reduced by etching an exposed one end of the channel pattern CP, and is not limited thereto.

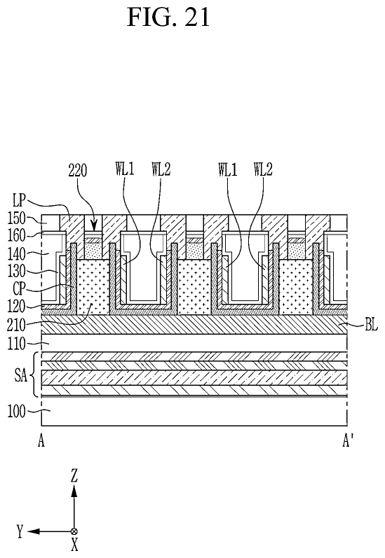

As shown in FIG. 21, a landing pad LP connected to the channel pattern CP may be formed by filling the first to third open parts OP1 to OP3.

In detail, a planarization process may then be performed by forming holes exposing a portion of an upper surface of the third insulating pattern 160 by patterning the landing pad LP, and then filling the upper insulating layer 150 in the holes. However, an order of forming the landing pad LP and the upper insulating layer 150 is not limited thereto. In example embodiments, the landing pad LP penetrating through the upper insulating layer 150 may be formed after forming and patterning the upper insulating layer 150.

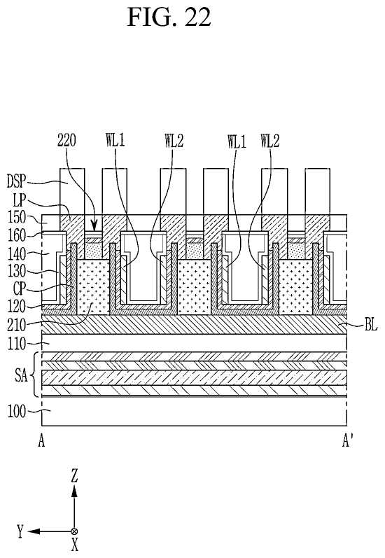

Finally, as shown in FIG. 22, the semiconductor device of FIGS. 1 through 6 may be formed by respectively forming data storage patterns DSP on the landing pads. Here, it is possible to sequentially form lower electrodes, a capacitor dielectric layer, and an upper electrode when the data storage pattern DSP includes a capacitor.

Although the embodiments of the present disclosure have been described in detail hereinabove, the scope of the present disclosure is not limited thereto. That is, various modifications and alterations made by those skilled in the art by using a basic concept of the present disclosure as defined in the following claims fall within the scope of the present disclosure.

What is claimed is:

1. A semiconductor device comprising:
a substrate;
a bit line on the substrate and extending in a first direction;
a first interlayer insulating layer on the bit line, and including a channel trench extending in a second direction crossing the first direction;
a second interlayer insulating layer on the first interlayer insulating layer;
a channel pattern in the channel trench;
a word line extending in the second direction and spaced apart from the channel pattern;
a gate insulating pattern between the channel pattern and the word line;
an insulating pattern on the word line; and
a landing pad connected to the channel pattern,
wherein the landing pad includes
a first protrusion between the channel pattern and the second interlayer insulating layer, and
a second protrusion between the channel pattern and the insulating pattern.

2. The semiconductor device of claim 1, wherein a bottom surface of the second protrusion is farther from an upper surface of the substrate than a bottom surface of the first protrusion is from the upper surface of the substrate.

3. The semiconductor device of claim 2, wherein the first protrusion is on the first interlayer insulating layer, and the second protrusion is on the gate insulating pattern.

4. The semiconductor device of claim 1, wherein
an upper surface of the channel pattern is in contact with the landing pad, and
the upper surface of the channel pattern is farther from an upper surface of the substrate than an upper surface of the gate insulating pattern is from the upper surface of the substrate.

5. The semiconductor device of claim 1, wherein a width of the first interlayer insulating layer in the first direction is greater than a width of the second interlayer insulating layer in the first direction.

6. The semiconductor device of claim 1, wherein
the channel pattern includes a first surface and a second surface, the first surface overlapping the first protrusion in the first direction, and the second surface opposite to the first surface, and
the first surface is in contact with the first protrusion, and the second surface is in contact with the second protrusion.

7. The semiconductor device of claim 6, wherein
the channel pattern further includes a third surface and a fourth surface, the third surface connected to the first surface and the second surface, and the fourth surface opposite to the third surface, and
the second protrusion is in contact with the third surface and the fourth surface.

8. The semiconductor device of claim 1, wherein the first protrusion overlaps the second protrusion in the first direction.

9. The semiconductor device of claim 8, wherein the second protrusion overlaps the channel pattern in the second direction.

10. A semiconductor device comprising:
a substrate;
a bit line on the substrate;
a channel pattern on the bit line, and extending to an upper surface of the bit line in a vertical direction;
a word line crossing the bit line and spaced apart from the channel pattern;
a gate insulating pattern between the channel pattern and the word line;
an insulating pattern on the word line; and
a landing pad connected to the channel pattern,
wherein the landing pad surrounds an upper surface and a side surface of one end of the channel pattern.

11. The semiconductor device of claim 10, wherein the landing pad includes
a first protrusion on a first surface of the channel pattern, and
a second protrusion on a second surface of the channel pattern that is opposite to the first surface, and
a bottom surface of the second protrusion is farther from the substrate than a bottom surface of the first protrusion is from the substrate.

12. The semiconductor device of claim 11, wherein
the channel pattern further includes
a third surface connected to the first surface and the second surface, and a fourth surface opposite to the third surface, and
the second protrusion is on the third surface and the fourth surface.

13. The semiconductor device of claim 12, wherein
the channel pattern includes an oxide semiconductor material, and
the upper surface and the first to fourth surfaces of the channel pattern are in contact with the landing pad.

14. The semiconductor device of claim 12, wherein
the channel pattern includes at least one of silicon, germanium, silicon-germanium, or a combination thereof,
the semiconductor device further comprises a silicide film between the channel pattern and the landing pad, and surrounding the upper surface and the first to fourth surfaces at the one end of the channel pattern.

15. The semiconductor device of claim 11, wherein the first protrusion overlaps the word line in a horizontal direction, and the second protrusion does not overlap the word line in the horizontal direction.

16. The semiconductor device of claim 10, wherein the upper surface of the channel pattern is farther from an upper surface of the substrate than an upper surface of the gate insulating pattern is from the upper surface of the substrate.

17. The semiconductor device of claim 16, wherein an upper surface of the word line is closer to the upper surface of the substrate than the upper surface of the channel pattern is to the upper surface of the substrate.

18. A method for fabricating a semiconductor device, the method comprising:
forming a bit line on a substrate;
stacking a first interlayer insulating layer and a second interlayer insulating layer on the bit line;
forming a channel trench by patterning the first interlayer insulating layer and the second interlayer insulating layer;
forming a channel pattern in the channel trench;
forming a gate insulating pattern on the channel pattern;
forming a word line on the gate insulating pattern, the word line crossing the bit line and spaced apart from the channel pattern;
forming an insulating pattern on the word line;
exposing a first surface of the channel pattern and a second surface opposite to the first surface by patterning the second interlayer insulating layer and the gate insulating pattern; and
forming a landing pad covering an upper surface of the channel pattern, and covering the first surface and the second surface of the channel pattern.

19. The method of claim 18, wherein the patterning of the gate insulating pattern comprises exposing a third surface of the channel pattern that is connected to the first surface and the second surface, and a fourth surface opposite to the third surface.

20. The method of claim 18, wherein the upper surface of the channel pattern is farther from an upper surface of the substrate than an upper surface of the gate insulating pattern is from the upper surface of the substrate.
